(19) United States
(12) Patent Application Publication
(10) Pub. No.: US 2022/0283488 A1
(43) Pub. Date: Sep. 8, 2022

(54) EUV MASK AND PHOTOMASK FABRICATED BY USING THE EUV MASK

(71) Applicant: SK hynix Inc., Gyeonggi-do (KR)

(72) Inventors: Suk Won PARK, Gyeonggi-do (KR); Chan Ha PARK, Gyeonggi-do (KR); Sang Ho LEE, Gyeonggi-do (KR); Chang Moon LIM, Gyeonggi-do (KR); Tae Kwon JEE, Gyeonggi-do (KR)

(21) Appl. No.: 17/461,130

(22) Filed: Aug. 30, 2021

(30) Foreign Application Priority Data
Mar. 2, 2021 (KR) 10-2021-0027474

(51) Int. Cl. G03F 1/24; G03F 1/54; G03F 1/48

(52) U.S. Cl. CPC G03F 1/24; G03F 1/54; G03F 1/48

(57) ABSTRACT

An Extreme UltraViolet (EUV) mask includes: a reflective layer over a substrate; a capping layer including a porous hydrogen trapping layer over the reflective layer; and an absorption layer over the capping layer.

### CROSS-REFERENCE TO RELATED APPLICATIONS

The present application claims priority of Korean Patent Application No. 10-2021-0027474, filed on Mar. 2, 2021, which is incorporated herein by reference in its entirety.

### BACKGROUND

### 1. Field

Various embodiments of the present invention relate to an Extreme UltraViolet (EUV) mask and a photomask fabricated by using the EUV mask.

### 2. Description of the Related Art

In order to increase the integration degree of a semiconductor device, a photolithography device using Extreme UltraViolet (EUV) light as a light source has been introduced. However, extreme ultraviolet light is greatly attenuated by the atmosphere and absorbed by almost all materials, so a transmission-type photomask used in an argon fluoride (ArF) photolithography process may not be used.

Therefore, in an EUV photolithography process, a photomask including a reflective layer is used.

### SUMMARY

Embodiments of the present invention are directed to an Extreme UltraViolet (EUV) mask capable of preventing defects that may be caused by hydrogen ions or hydrogen gas, and a photomask fabricated by using the EUV mask.

In accordance with an embodiment of the present invention, an Extreme UltraViolet (EUV) mask includes: a reflective layer over a substrate; a capping layer including a porous hydrogen trapping layer over the reflective layer; and an absorption layer over the capping layer.

In accordance with another embodiment of the present invention, an EUV mask includes: a substrate including a first surface and a second surface to opposite each other; a reflective layer formed over the first surface of the substrate; a capping layer formed over the reflective layer and including a porous hydrogen trapping layer; an absorption layer formed over the capping layer; and a conductive coating layer formed over the second surface of the substrate.

In accordance with yet another embodiment of the present invention, a photomask includes: a substrate including a first surface and a second surface to opposite each other; a reflective layer formed over the first surface of the substrate; a capping layer formed over the reflective layer and including a porous hydrogen trapping layer; a light absorption pattern formed over the capping layer and including an opening through which extreme ultraviolet light pass; and a conductive coating layer formed over the second surface of the substrate.

These and other features and advantages of the present invention will become better understood from the following drawings and detailed description of the present invention.

### BRIEF DESCRIPTION OF THE DRAWINGS

FIG. 1 is a cross-sectional view illustrating an Extreme UltraViolet (EUV) mask in accordance with an embodiment of the present invention.

FIGS. 2 to 7 are cross-sectional views illustrating EUV masks in accordance with embodiments of the present invention.

FIG. 8 is a cross-sectional view illustrating a photomask fabricated by using the EUV mask in accordance with an embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate however also a case where a third layer exists between the first layer and the second layer or the substrate.

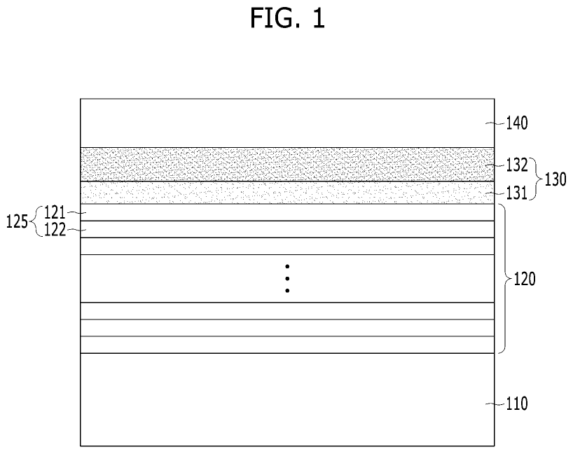

FIG. 1 is a cross-sectional view illustrating an Extreme UltraViolet (EUV) mask in accordance with an embodiment of the present invention.

Referring to FIG. 1, the EUV mask may be a substrate for fabricating a photomask that may be mounted on a photolithography device by using extreme ultraviolet light as a light source. The EUV mask may refer to an EUV blank mask.

The EUV mask may include a mask substrate 110, a reflective layer 120, a capping layer 130, and a light absorbing layer 140.

The mask substrate 110 may be formed of a dielectric material, glass, a semiconductor, or a metal material. The mask substrate 110 may be formed of a material having a low thermal expansion coefficient. For example, the mask substrate 110 may have a thermal expansion coefficient of 0±1.0×10⁻⁷/° C. at approximately 20° C.

Also, the mask substrate 110 may be formed of a material having excellent smoothness, flatness, and resistance to a cleaning solution. For example, the mask substrate 110 may be formed of synthetic quartz glass, quartz glass, alumino silicate glass, soda lime glass, LTEM (low thermal expansion material) glass, such as SiO₂—TiO₂ glass (binary system (SiO₂—TiO₂) and ternary system (SiO₂—TiO₂—SnO₂)), crystallized glass in which a β-quartz solid solution is educed, monocrystalline silicon, or SiC. The mask substrate 110 included in an EUV mask may be required to have low thermal expansion characteristics. Accordingly, the mask substrate 110 may be formed of, for example, a multi-component glass material.

The reflective layer 120 may be formed over the mask substrate 110. The reflective layer 120 may reflect extreme ultraviolet (EUV) light. The reflective layer 120 may have a multi-layer mirror structure. In the reflective layer 120, a material layer having a high refractive index and a material layer having a low refractive index may be alternately stacked a plurality of times.

The reflective layer 120 may include a first reflective layer 121 and a second reflective layer 122 that are alternately stacked. The first reflective layer 121 and the second reflective layer 122 may include material layers having different refractive indices for extreme ultraviolet light. For example, when the first reflective layer 121 is a material layer having a low refractive index, the second reflective layer 122 may be a material layer having a high refractive index, and when the first reflective layer 121 is a material layer having a high refractive index, the second reflective layer 122 may be a material layer having a low refractive index. The reflective layer 120 may include a periodic multi-layer of the first reflective layer 121/the second reflective layer 122. The reflective layer 120 may include the first reflective layer 121 and the second reflective layer 122 that are repeatedly formed at approximately 20 to 60 periods.

The first reflective layer 121 and the second reflective layer 122 may form a reflective pair 125. The reflective layer 120 may include approximately 20 to 60 reflective pairs 125. It is obvious to those skilled in the art that this embodiment of the present invention is not limited thereto, and more or less reflective pairs 125 may be used as needed.

For example, the reflective layer 120 may be formed of a molybdenum (Mo)/silicon (Si) periodic multi-layer, a Mo compound/Si compound periodic multi-layer, a ruthenium (Ru)/Si periodic multi-layer, and a Mo/beryllium (Be) periodic multi-layer, Si/Niobium (Nb) periodic multi-layer, a MoC/Si periodic multi-layer, a Mo/MoC/Si periodic multi-layer, a Si/Mo/Ru periodic multi-layer, a Si/Mo/Ru/Mo periodic multi-layer, or a Si/Ru/Mo/Ru periodic multi-layer.

The material forming the reflective layer 120 and the film thickness of each reflective layer may be controlled according to the wavelength band of applied EUV light or the reflection index of the EUV light required by the reflective layer 120.

According to the embodiment of the present invention, it may be described that a molybdenum (Mo)/silicon (Si) periodic multi-layer may be included as the reflective layer 120. For example, the first reflective layer 121 may be formed of silicon, and the second reflective layer 122 may be formed of molybdenum.

It is illustrated in FIG. 1 that the reflective layer 120 includes the same number of the first reflective layers 121 and the second reflective layers 122, however the concept and spirit of the present invention are not limited thereto. In the reflective layer 120, the difference between the number of the first reflective layers 121 and the number of the second reflective layers 122 may be 1.

The reflective layer 120 may be formed by using a sputtering process such as, for example, DC sputtering, RF sputtering, ion beam sputtering, or the like, however the concept and spirit of the present invention are not limited thereto. For example, when a Mo/Si periodic multi-layer is formed by using ion beam sputtering, depositing a Si layer by using a Si target as a target and using Ar gas as a sputtering gas, and depositing a Mo layer by using a Mo target as a target and using Ar gas as a sputtering gas may be taken as one period, and the Si layer and the Mo layer may be formed alternately.

A capping layer 130 may be formed over the reflective layer 120. The capping layer 130 may serve to protect the reflective layer 120. For example, the capping layer 130 may serve to protect the reflective layer 120 from mechanical damage. Also, for example, the capping layer 130 may serve to protect the reflective layer 120 from chemical damage. In an embodiment, the capping layer 130, may prevent defects caused by hydrogen by applying at least one porous layer and thereby securing a hydrogen transfer path. In other words, the porous layer may serve as the hydrogen transfer path for moving and discharging hydrogen ions or hydrogen gas introduced from the outside through the pores between the crystal grains to the outside of the EUV mask.

The capping layer 130 may include a stacked structure. For example, the capping layer 130 may include a stacked structure of a first capping layer 131 and a second capping layer 132. The first capping layer 131 and the second capping layer 132 may have different thin film densities. The capping layer 130 may include a porous first capping layer 131 and a second capping layer 132 having a denser structure than the first capping layer 131. The first capping layer 131 may include a plurality of pores for moving and discharging hydrogen ions or hydrogen gas introduced from the outside to the outside of the EUV mask. The first capping layer 131 may refer to a hydrogen trapping layer. The first capping layer 131 may be formed on the reflective layer 120. The first capping layer 131 may contact the reflective layer 120.

The first capping layer 131 and the second capping layer 132 may be formed of the same material. The first capping layer 131 and the second capping layer 132 may be formed by a sputtering process. The first capping layer 131 and the second capping layer 132 may be formed of a material of which the number of pores and density in the film can be controlled through pressure control. The first capping layer 131 and the second capping layer 132 may include ruthenium (Ru) or a ruthenium compound, however the concept and spirit of the present invention are not limited thereto. The ruthenium compound may be formed of a compound containing ruthenium (Ru) and at least one selected from a group including niobium (Nb), zirconium (Zr), molybdenum (Mo), yttrium (Y), boron (B), lanthanum (La), and combinations thereof.

The pressure in a chamber for forming the first capping layer 131 may be set higher than the pressure in a chamber for forming the second capping layer 132. When the pressure in a sputtering chamber for forming a thin film is high, the amount of argon (Ar) gas remaining in the chamber may increase, and the density of Ar plasma may increase. Accordingly, since the Ar sputtering effect is increased, the deposition rate of a thin film may be increased and the density may be decreased, which may lead to generation of pores between the crystal grains, thereby forming a porous thin film structure.

The capping layer 130 including the first capping layer 131 and the second capping layer 132 may be formed to have a total thickness that minimizes the effect on the reflectivity of the EUV mask. The total thickness of the capping layer 130 may be controlled not to exceed approximately 100 Å. In other words, the capping layer 130 may be formed to have a thickness of 100 Å or less. For example, the capping layer 130 may be formed in a thickness range of approximately 5 Å to 100 Å. According to an embodiment of the present invention, the thickness of the first capping layer 131 may be controlled to be thinner than the thickness of the second capping layer 132.

According to an embodiment of the present invention, by applying the capping layer 130 including a porous layer, a space to be occupied by hydrogen ions or hydrogen gases introduced from the outside may be formed in the pores between the crystal grains. As a result, blister defects that may be caused by hydrogen may be prevented. Moreover, the porous layer according to the embodiment of the present invention does not collect or store hydrogen ions or hydrogen gas. Thus, the hydrogen ions or hydrogen gases may move to the outer side of the mask along the pores of the first capping layer 131 and be discharged and this may minimize the occurrence of defects caused by hydrogen.

A light absorbing layer 140 may be formed over the capping layer 130. The light absorbing layer 140 may be formed of a material having a low reflection index of extreme ultraviolet light while absorbing extreme ultraviolet light. The light absorbing layer 140 may be formed of a material having excellent chemical resistance. Also, the light absorbing layer 140 may be formed of a material that may be removed by an etching process or other processes.

The light absorbing layer 140 may be formed of a material containing tantalum (Ta) as a main component. The light absorbing layer 140 may include a tantalum as a main component and at least one element selected among hafnium (Hf), silicon (Si), zirconium (Zr), germanium (Ge), boron (B), nitrogen (N) and hydrogen (H). For example, the light absorbing layer 140 may be formed of TaN, TaHf, TaHfN, TaBSi, TaBSiN, TaB, TaBN, TaSi, TaSiN, TaGe, TaGeN, TaZr, TaZrN, or a combination thereof.

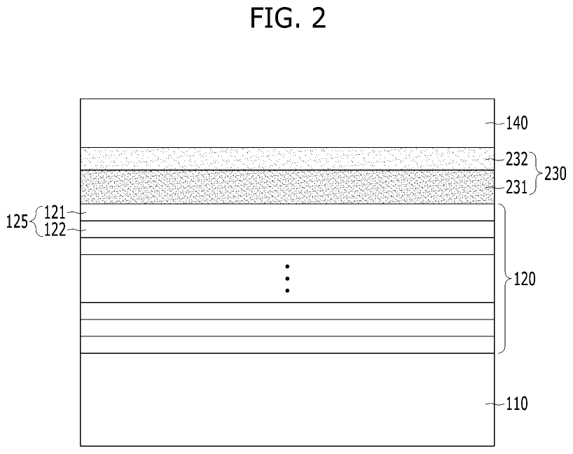

FIGS. 2 to 7 are cross-sectional views illustrating the EUV masks in accordance with embodiments of the present invention. The EUV mask illustrated in FIGS. 2 to 7 may include the mask substrate 110, the reflective layer 120, and the light absorbing layer 140 that are shown in FIG. 1. Description of these elements may be omitted.

Referring to FIG. 2, a capping layer 230 may include a dense first capping layer 231 and a porous second capping layer 232. The capping layer 230 may include a stacked structure of the first capping layer 231 and the second capping layer 232. The second capping layer 232 may include a plurality of pores for moving and discharging hydrogen ions or hydrogen gas introduced from the outside to the outside of the EUV mask. The second capping layer 232 may refer to a hydrogen trapping layer. The first capping layer 231 may be formed on the reflective layer 120. The first capping layer 231 may contact the reflective layer 120.

The first capping layer 231 and the second capping layer 232 may be formed of the same material. The first capping layer 231 and the second capping layer 232 may be formed by a sputtering process. The first capping layer 231 and the second capping layer 232 may include a material of which the number of pores and density in the film can be controlled through pressure control. The first capping layer 231 and the second capping layer 232 may include ruthenium (Ru) or a ruthenium compound, however the concept and spirit of the present invention are not limited thereto. The ruthenium compound may be formed of a compound containing ruthenium (Ru) and at least one selected from the group including niobium (Nb), zirconium (Zr), molybdenum (Mo), yttrium (Y), boron (B), lanthanum (La), and combinations thereof.

The pressure in a chamber for forming the second capping layer 232 may be set higher than the pressure in a chamber for forming the first capping layer 231. When the pressure in the sputtering chamber for forming a thin film is high, the amount of argon (Ar) gas remaining in the chamber may increase, and the density of Ar plasma may increase. Accordingly, since the Ar sputtering effect is increased, the deposition rate of the thin film may be increased and the density may be decreased, which may lead to generation of pores between the crystal grains, thereby forming a porous thin film structure.

The capping layer 230 including the first capping layer 231 and the second capping layer 232 may be formed to have a total thickness that may minimize the effect on the reflectivity of the EUV mask. The total thickness of the capping layer 230 may be controlled not to exceed approximately 100 Å. In other words, the capping layer 230 may be formed to have a thickness of 100 Å or less. For example, the capping layer 230 may be formed in a thickness range of approximately 5 Å to 100 Å. According to an embodiment of the present invention, the thickness of the second capping layer 232 may be controlled to be thinner than the thickness of the first capping layer 231.

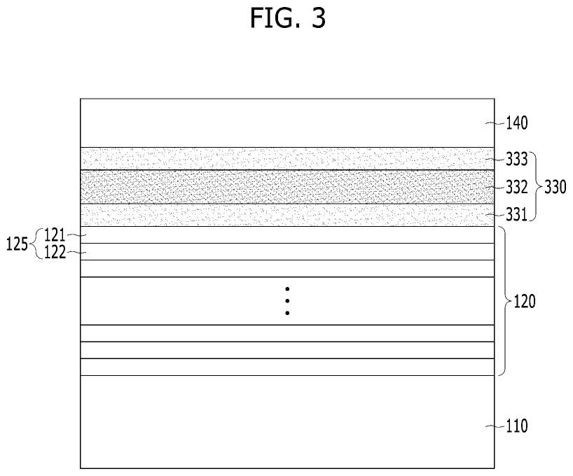

Referring to FIG. 3, a capping layer 330 may include a porous first capping layer 331, a third capping layer 333, and a dense second capping layer 332 formed between the first and third capping layers 331 and 333. The capping layer 330 may include a structure in which the first to third capping layers 331, 332, and 333 are sequentially stacked. The first capping layer 331 and the third capping layer 333 may include a plurality of pores for moving and discharging hydrogen ions or hydrogen gas introduced from the outside to the outside of the EUV mask. Each of the first capping layer 331 and the third capping layer 333 may refer to a hydrogen trapping layer. The first capping layer 331 may be formed on the reflective layer 120. The first capping layer 331 may contact the reflective layer 120.

The first to third capping layers 331, 332, and 333 may be formed of the same material. The first to third capping layers 331, 332, and 333 may be formed by a sputtering process. The first to third capping layers 331, 332, and 333 may include a material of which the number of pores and density in the film can be controlled through pressure control. The first to third capping layers 331, 332, and 333 may include ruthenium (Ru) or a ruthenium compound, however the concept and spirit of the present invention are not limited thereto. The ruthenium compound may be formed of a compound containing ruthenium (Ru) and at least one selected from the group including niobium (Nb), zirconium (Zr), molybdenum (Mo), yttrium (Y), boron (B), lanthanum (La), and combinations thereof.

The pressure in a chamber for forming the first and third capping layers 331 and 333 may be set higher than the pressure in a chamber for forming the second capping layer 332. When the pressure in a sputtering chamber for forming a thin film is high, the amount of argon (Ar) gas remaining in the chamber may increase, and the density of Ar plasma may increase. Accordingly, since the Ar sputtering effect is increased, the deposition rate of the thin film may be increased and the density may be decreased, which may lead to generation of pores between the crystal grains, thereby forming a porous thin film structure.

The capping layer 330 including the first to third capping layers 331, 332, and 333 may be formed to have a total thickness that minimizes the effect on the reflectivity of the EUV mask. The total thickness of the capping layer 330 may be controlled not to exceed approximately 100 Å. For example, the capping layer 330 may be formed in a thickness range of approximately 5 Å to 100 Å. The first and third capping layers 331 and 333 may be controlled to have a thickness thinner than the thickness of the second capping layer 332.

According to another embodiment of the present invention, the capping layer 330 may include the dense first capping layer 331, the third capping layer 333 and the porous second capping layer 332. In this case, the thickness of the second capping layer 332 may be controlled to be thinner than those of the first and third capping layers 331 and 333.

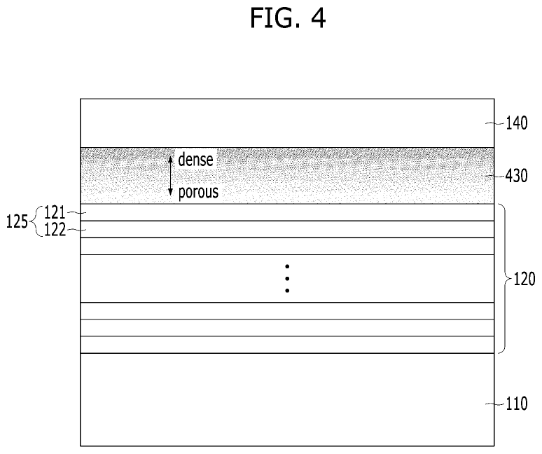

Referring to FIG. 4, a capping layer 430 may be formed as a single layer in which the density of the thin film changes continuously. In other words, as the capping layer 430 is closer the reflective layer 120, pores in the film may increase. Also, as the capping layer 430 is farther from the reflective layer 120, pores in the film may decrease and the density of the film may increase.

The capping layer 430 may be formed by a sputtering process. The capping layer 430 may include a material of which the number of pores and density in the film can be controlled through pressure control. The capping layer 430 may include ruthenium (Ru) or a ruthenium compound, however the concept and spirit of the present invention are not limited thereto. The ruthenium compound may be formed of a compound containing ruthenium (Ru) and at least one selected from the group including niobium (Nb), zirconium (Zr), molybdenum (Mo), yttrium (Y), boron (B), lanthanum (La), and a combination thereof.

The sputtering process for forming the capping layer 430 may be controlled in such a manner that the pressure in the chamber is the highest when it is close to the reflective layer 120, and the pressure may gradually decrease in a direction away from the reflective layer 120. The pressure is the lowest at a portion that is the farthest from the reflective layer 120. When the pressure in the sputtering chamber for forming a thin film is high, the amount of argon (Ar) gas remaining in the chamber may increase, and the density of the Ar plasma may increase. Accordingly, since the Ar sputtering effect is increased, the deposition rate of the thin film may be increased and the density may be decreased with pores formed between the crystal grains. Therefore, a porous thin film structure may be formed.

The capping layer 430 may be formed to have a thickness that does not exceed approximately 100 Å in order to minimize the effect on the reflectivity of the EUV mask. In other words, the capping layer 430 may be formed to have a thickness of 100 Å or less. For example, the capping layer 430 may be formed in a thickness range of approximately 5 Å to 100 Å.

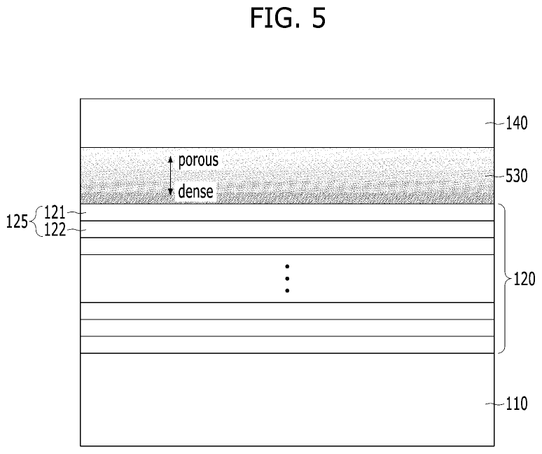

Referring to FIG. 5, a capping layer 530 may be formed as a single layer in which the thin film density changes continuously. The capping layer 530 may be formed to be denser as it goes closer to the reflective layer 120 and to have more pores as it goes further from the reflective layer 120.

The capping layer 530 may be formed by a sputtering process. The capping layer 530 may include a material of which the number of pores and density in the film can be controlled through pressure control. The capping layer 530 may include ruthenium (Ru) or a ruthenium compound, however the concept and spirit of the present invention are not limited thereto. The ruthenium compound may be formed of a compound containing ruthenium (Ru) and at least one selected from the group including niobium (Nb), zirconium (Zr), molybdenum (Mo), yttrium (Y), boron (B), lanthanum (La), and combinations thereof.

The sputtering process for forming the capping layer 530 may be controlled in such a manner that the pressure in the chamber is the lowest when it is close to the reflective layer 120, and the pressure may gradually increase, and the pressure is the highest at a portion farthest from the reflective layer 120. When the pressure in the sputtering chamber for forming a thin film is high, the amount of argon (Ar) gas remaining in the chamber may increase, and the density of the Ar plasma may increase. Accordingly, since the Ar sputtering effect is increased, the deposition rate of the thin film may be increased and the density may be decreased with pores formed between the crystal grains. Therefore, a porous thin film structure may be formed.

The capping layer 530 may be formed to have a thickness that does not exceed approximately 100 Å in order to minimize the effect on the reflectivity of the EUV mask. In other words, the capping layer 530 may be formed to have a thickness of 100 Å or less. For example, the capping layer 530 may be formed in a thickness range of approximately 5 Å to 100 Å.

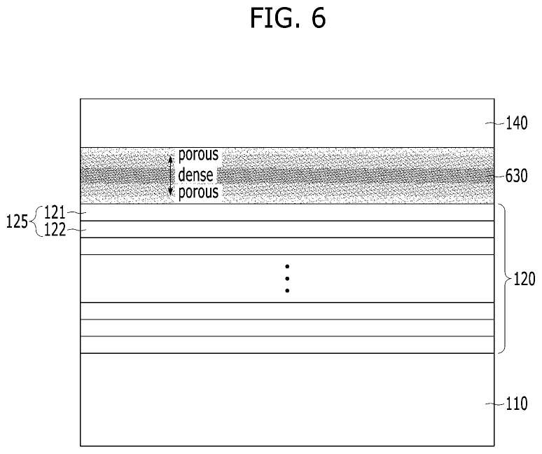

Referring to FIG. 6, a capping layer 630 may be formed as a single layer in which the thin film density changes continuously. The capping layer 630 may be formed to have most pores in the layer at a portion closest to the reflective layer 120 and at a portion farthest from the reflective layer 120 and to be denser as it goes closer to the central portion of the capping layer 630.

The capping layer 630 may be formed by a sputtering process. The capping layer 630 may include a material of which the number of pores and density in the film can be controlled through pressure control. The capping layer 630 may include ruthenium (Ru) or a ruthenium compound, however the concept and spirit of the present invention are not limited thereto. The ruthenium compound may be formed of a compound containing ruthenium (Ru) and at least one selected from the group including niobium (Nb), zirconium (Zr), molybdenum (Mo), yttrium (Y), boron (B), lanthanum (La), and combinations thereof.

The sputtering process for forming the capping layer 630 may be controlled in such a manner that the pressure in the chamber is the highest at a portion closest to the reflective layer 120 and at a portion farthest from the reflective layer 120, and the pressure gradually decrease or gradually increases, and the pressure in the chamber is the lowest at the central portion of the capping layer 630. When the pressure in the sputtering chamber for forming a thin film is high, the amount of argon (Ar) gas remaining in the chamber may increase, and the density of the Ar plasma may increase. Accordingly, since the Ar sputtering effect is increased, the deposition rate of the thin film may be increased and the density may be decreased with pores formed between the crystal grains. Therefore, a porous thin film structure may be formed.

The capping layer 630 may be formed to have a thickness that does not exceed approximately 100 Å in order to minimize the effect on the reflectivity of the EUV mask. In other words, the capping layer 630 may be formed to have a thickness of 100 Å or less. For example, the capping layer 630 may be formed in a thickness range of approximately 5 Å to 100 Å.

According to another embodiment of the present invention, the capping layer 630 may be formed as a single layer in which the thin film density changes continuously. The capping layer 630 may be formed to have most pores in the layer at the central portion of the capping layer 630 and to become denser as it goes farther from the central portion of the capping layer 630.

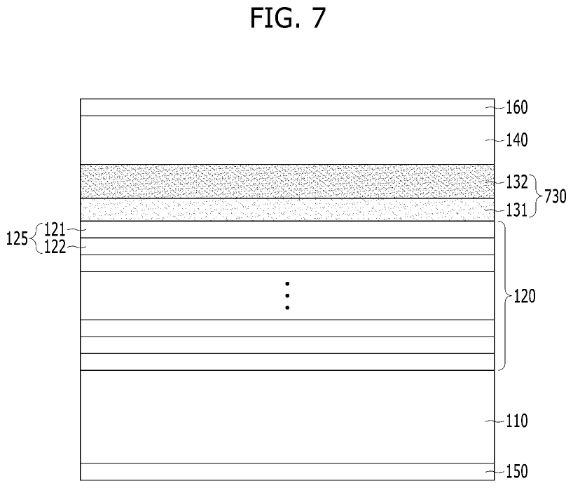

Referring to FIG. 7, in the EUV mask in accordance with an embodiment of the present invention, a conductive coating layer 150 may be formed on the rear surface of the mask substrate 110. Although a technical feature of FIG. 7 is applied to the structure of the EUV mask shown in FIG. 1, the technology feature illustrated in FIG. 7 in accordance with an embodiment of the present invention may also be applied to the embodiments described in FIGS. 2 to 6.

The conductive coating layer 150 may be used to fix a photomask fabricated by using the EUV mask to an electrostatic chuck of a lithography device during a photolithography process.

The conductive coating layer 150 may include a conductive material containing chromium (Cr) or tantalum (Ta). For example, the conductive coating layer 150 may be formed of at least one among Cr, chromium nitride (CrN), and tantalum boride (TaB). The conductive coating layer 150 may include a metal oxide or a metal nitride having conductivity. For example, the conductive coating layer 150 may be formed of at least one among titanium nitride (TiN), zirconium nitride (ZrN), hafnium nitride (HfN), ruthenium oxide (RuO₂), zinc oxide (ZnO₂), and iridium oxide (IrO₂).

A low reflective layer 160 may be formed over the light absorbing layer 140. The low reflective layer 160 may provide relatively low reflectivity in the wavelength band of the test light, for example, in the wavelength band of approximately 190 nm to 260 nm, during the test of the pattern elements formed in the photomask fabricated by using the EUV mask. In this way, the low reflective layer 160 may serve to obtain sufficient contrast.

The low reflective layer 160 may be formed of a material including tantalum containing one or more elements selected from nitrogen, oxygen, boron, and hydrogen, for example, TaBO, TaBNO, TaOH, and TaONH. The low reflective layer 160 may be formed by a sputtering process, however, the concept and spirit of the present invention are not limited thereto.

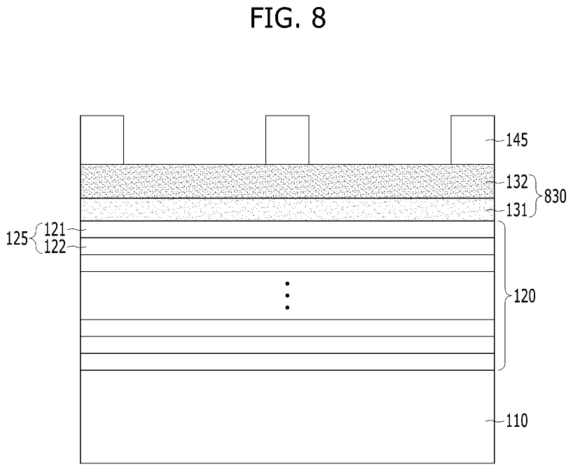

FIG. 8 is a cross-sectional view illustrating a photomask fabricated by using the EUV mask in accordance with an embodiment of the present invention. FIG. 8 illustrates a photomask fabricated by using the EUV mask shown in FIG. 1, however, it should be understood by those skilled in the art in view of the present disclosure that it is possible to fabricate all photomasks in accordance with the other embodiments of the present invention shown in FIGS. 2 to 7.

The photomask in accordance with the embodiment of the present invention may be a reflective photomask that may be used for a photolithography process using an EUV wavelength range, for example, an exposure wavelength of approximately 13.5 nm.

Also, the photomask in accordance with the embodiment of the present invention may be fabricated by patterning the light absorbing layer 140 and/or the low reflective layer 160 included in the EUV mask of FIGS. 1 to 7. Since the description on the mask substrate 110, the reflective layer 120, and the capping layer 130 including the porous layer serving as a hydrogen transfer path in the photomask in accordance with the embodiment of the present invention is substantially similar to what is described in FIGS. 1 to 7, the description on it will be omitted herein.

Referring to FIG. 8, a photomask may include a mask substrate 110, a reflective layer 120, a capping layer 130 including a porous layer serving as a hydrogen transfer path, and a light absorption pattern 145.

The light absorption pattern 145 may be disposed over the capping layer 130. The light absorption pattern 145 may include an opening through which extreme ultraviolet light pass.

According to the embodiment of the present invention, an EUV mask capable of preventing defects that may be caused by hydrogen ions or hydrogen gas, and a photomask fabricated by using the EUV mask may be provided.

While the present invention has been described with respect to specific embodiments, it will be apparent to those skilled in the art that various changes and modifications may be made without departing from the spirit and scope of the invention as defined in the following claims.

What is claimed is:

1. An Extreme UltraViolet (EUV) mask, comprising:
a reflective layer over a substrate;
a capping layer including a porous hydrogen trapping layer over the reflective layer; and
an absorption layer over the capping layer.

2. The EUV mask of claim 1, wherein the capping layer includes a stacked structure of a first capping layer and a second capping layer which have different thin film densities.

3. The EUV mask of claim 2, wherein the first capping layer includes a porous material, and the second capping layer includes a dense material.

4. The EUV mask of claim 2, wherein the first capping layer includes a dense material, and the second capping layer includes a porous material.

5. The EUV mask of claim 1, wherein the capping layer includes a stacked structure of a first capping layer, a second capping layer, and a third capping layer which have different thin film densities.

6. The EUV mask of claim 5, wherein the first capping layer and the third capping layer include a porous material, and the second capping layer includes a dense material.

7. The EUV mask of claim 5, wherein the first capping layer and the third capping layer include a dense material, and the second capping layer includes a porous material.

8. The EUV mask of claim 1, wherein the capping layer includes a single layer whose thin film density changes continuously.

9. The EUV mask of claim 8, wherein the capping layer has more pores inside as the capping layer becomes closer to the reflective layer, and
the capping layer has denser film quality as the capping layer becomes farther to the reflective layer.

10. The EUV mask of claim 8, wherein the capping layer has denser film quality as the capping layer becomes closer to the reflective layer, and
the capping layer has more pores inside as the capping layer becomes farther to the reflective layer.

11. The EUV mask of claim 8, wherein the capping layer has the most dense film quality at a central portion, and
the pores in the capping layer gradually increase from the central portion toward outside.

12. The EUV mask of claim 8, wherein the capping layer has the most pores inside at a central portion, and
a film quality of the capping layer becomes denser from the central portion toward outside.

13. The EUV mask of claim 1, wherein the capping layer includes ruthenium (Ru) or a ruthenium compound.

14. The EUV mask of claim 1, wherein the reflective layer includes a first reflective layer and a second reflective layer that are alternately stacked.

15. The EUV mask of claim 14, wherein the reflective layer includes a high refractive material layer and a low refractive material layer that are alternately stacked.

16. The EUV mask of claim 1, wherein the reflective layer includes molybdenum (Mo)/silicon (Si) periodic multi-layer.

17. An Extreme UltraViolet (EUV) mask, comprising:
a substrate including a first surface and a second surface to opposite each other;
a reflective layer formed over the first surface of the substrate;
a capping layer formed over the reflective layer and including a porous hydrogen trapping layer;
an absorption layer formed over the capping layer; and
a conductive coating layer formed over the second surface of the substrate.

18. The EUV mask of claim 17, further comprising:
a low reflective layer formed over the absorption layer.

19. A photomask, comprising:
a substrate including a first surface and a second surface to opposite each other;
a reflective layer formed over the first surface of the substrate;
a capping layer formed over the reflective layer and including a porous hydrogen trapping layer;
a light absorption pattern formed over the capping layer and including an opening through which extreme ultraviolet light pass; and
a conductive coating layer formed over the second surface of the substrate.
